(19) United States
(12) Patent Application Publication
(10) Pub. No.: US 2025/0004015 A1
(43) Pub. Date: Jan. 2, 2025

(54) INSTRUMENT AND MEASUREMENT TRANSLATOR USING MACHINE LEARNING

(71) Applicant: Tektronix, Inc., Beaverton, OR (US)

(72) Inventors: Sam J. Strickling, Cypress, OR (US); John J. Pickerd, Hillsboro, OR (US); Kan Tan, Portland, OR (US); Justin E. Patterson, Honolulu, HI (US)

(21) Appl. No.: 18/746,902

(22) Filed: Jun. 18, 2024

Related U.S. Application Data
(60) Provisional application No. 63/523,621, filed on Jun. 27, 2023.

(51) Int. Cl. G01R 13/02

(52) U.S. Cl. CPC G01R 13/029

(57) ABSTRACT

A test and measurement system includes a first test and measurement instrument having an input to allow the test and measurement instrument to receive signals from one or more devices under test (DUT), and one or more digitizers to convert the signals from the one or more DUTs to digital waveforms, a machine learning network, and one or more processors to: perform one or more measurements of the digital waveforms, send the one or more measurements of the digital waveforms to the machine learning network as an input, use the machine learning network to translate the one or more measurements to measurements made by a reference instrument to produce one or more translated measurements, the reference instrument being more accurate than the first test and measurement instrument, and determine whether the DUT meets a performance requirement based upon the one or more translated measurements.

### CROSS-REFERENCE TO RELATED APPLICATIONS

This disclosure is a non-provisional of and claims benefit from U.S. Provisional Application No. 63/523,621, titled “INSTRUMENT AND MEASUREMENT TRANSLATOR USING MACHINE LEARNING,” filed on Jun. 27, 2023, the disclosure of which is incorporated herein by reference in its entirety.

### TECHNICAL FIELD

This disclosure relates to test and measurement instruments, and more particularly to machine-learning-based measurement translators for test and measurement instruments.

### BACKGROUND

Customers who use test and measurement instruments, for example, oscilloscopes, in their manufacturing (“MFG”) processes generally desire ways to make their manufacturing processes less expensive, faster, or both. Some customers using test equipment on the manufacturing line may have 100 or more test stations making measurements to test, tune, and qualify the devices they are manufacturing. High quality, and therefore more expensive, test and measurement instruments provide more accurate measurements, but raises the costs.

Lower cost instruments generally lead to lower performance for certain measurements, resulting in error in those measurements. This can then result in devices under test (DUT) passing tests that they did not actually pass, which can cause failures when the customer of the manufacturer employs the device in operation. Measurements with error can also cause scrapping of devices that would have passed with correct measurements.

For example, a customer may want to use ET, equivalent time, oscilloscopes to do as many of their high bandwidth measurements as possible. Equivalent time oscilloscopes (“scope”) cost much less than an RT, real time, scope. The manufacturer would only use the RT scope for situations where the ET scope was not capable of performing the measurement. This may cause many problems such as those mentioned above for both the manufacturer and the end customer.

### BRIEF DESCRIPTION OF THE DRAWINGS

FIG. 1 shows an embodiment of a translator system in a training configuration.

FIG. 2 shows an embodiment of a translator system in a runtime configuration.

FIG. 3 shows an embodiment of a translator system using JNB to DPOJET in a training configuration.

FIGS. 4-5 an embodiment of a translator system using JNB to DPOJET in a runtime configuration.

FIG. 6 shows an embodiment of a translator system using primary component analysis (PCA) in a training configuration.

FIG. 7 shows an embodiment of a translator system using primary component analysis (PCA) in a runtime configuration.

FIG. 8 shows an embodiment of a translator system using measurements and statistics in a training configuration.

FIG. 9 shows an embodiment of a translator system using measurements and statistics in a runtime configuration.

FIG. 10 shows an embodiment of a translator system using PCA, measurements and statistics in a training configuration.

FIG. 11 shows an embodiment of a translator system using PCA, measurements and statistics in a runtime configuration.

FIGS. 12 and 13 show an embodiment of a measurement package translation system in a training configuration, and a runtime configuration, respectively.

FIG. 14 shows an embodiment of a translator system for test instruments with integrated measurement software packages in a training configuration.

FIG. 15 shows an embodiment of a translator system for test instruments with integrated measurement software packages in a runtime configuration.

### DETAILED DESCRIPTION

The embodiments herein enable a customer to use a lower cost digitizing instrument to perform measurements on the manufacturing line. However, lower cost normally means lower performance for certain measurements, resulting in errors in those measurements. Therefore, embodiments herein generally allow a user to take measurements on the lower performing manufacturing test instrument, for example an ET scope as mentioned above, and translate that measurement using neural networks, or other machine learning modules, into what would have been obtained on a higher performing reference test instrument, such as the RT scope mentioned above. For example, current practice, high bandwidth oscilloscopes would apply a bandwidth enhancement filter (BWE) to extend the bandwidth of the scope and make risetime measurements more accurate for fast edge waveforms. The embodiments here can perform these and other enhancements and transform measurements from a manufacturing test instrument to match measurements for higher performing reference instrument using machine learning.

Embodiments herein differ from current state of the art in that the embodiments use neural networks to take in measurements and statistics from a manufacturing test instrument. Some embodiments may as an option also take in the parameters of that instrument which are responsible for the error in the measurement, and then associate that with what the ideal measurement should be.

Test instruments may contain digitizers and are generally receiving signals as input and then measurement software (SW) applications or packages produce measurements and statistics on the digitized signal waveforms. Test instruments may include but are not limited to RT oscilloscopes, ET oscilloscopes, margin testers, BER test systems, real time spectrum analyzers, volt meters, current meters, etc. Thus, measurement error may be in part due to differences in the test instrument hardware, and also in part due to differences in measurement SW package algorithms. Embodiments of the disclosure allow for both areas to be considered in the prediction for the translation from a MFG test instrument/measurement set to a reference test instrument/measurement set.

The figures here use the same reference number for different components of the system, whether the system uses those portions in the same environment. Further, some figures may refer to particular components that later figures do not. Unless otherwise specified, the components not referred to are assumed to also exist in similar figures,

Most, if not all, test, and measurement instruments, referred to here as test instruments, employ digitizers to convert the analog signals received from the devices under test to digital waveforms. Digitizers generally have specific characteristics and operating parameters. Some figures will discuss the embodiments in more general terms using digitizers, and specific examples may employ specific instruments and measurements.

This portion of the discussion will address test instruments independent of any measurement packages used. Different measurement packages may use different measures for the same or similar measurements. For example, the DPOJET measurement SW package from Tektronix may measure jitter, noise, timing, and perform eye analysis on RT scopes. Other packages, such as the JNB measurement SW package from Tektronix may measure jitter, noise, and BER (bit error rate) on ET scopes. The machine learning system, such as a neural network, translates the measurements based upon parameters of the test instrument and on differences between the measurement software used on a lower cost, less accurate manufacturing instrument, and the software used on the higher cost, more accurate reference instruments. In the figures, the measurements packages referred to as 1 and 2 differentiate the MFG package from the reference package and do not indicate that all embodiments using a package identified with a 1 as the same package across all embodiments. Different configurations and different elements may use different packages and are identified by their reference numbers. The measurements resulting from the translation to the higher accuracy instrument are referred to here as the translated measurements.

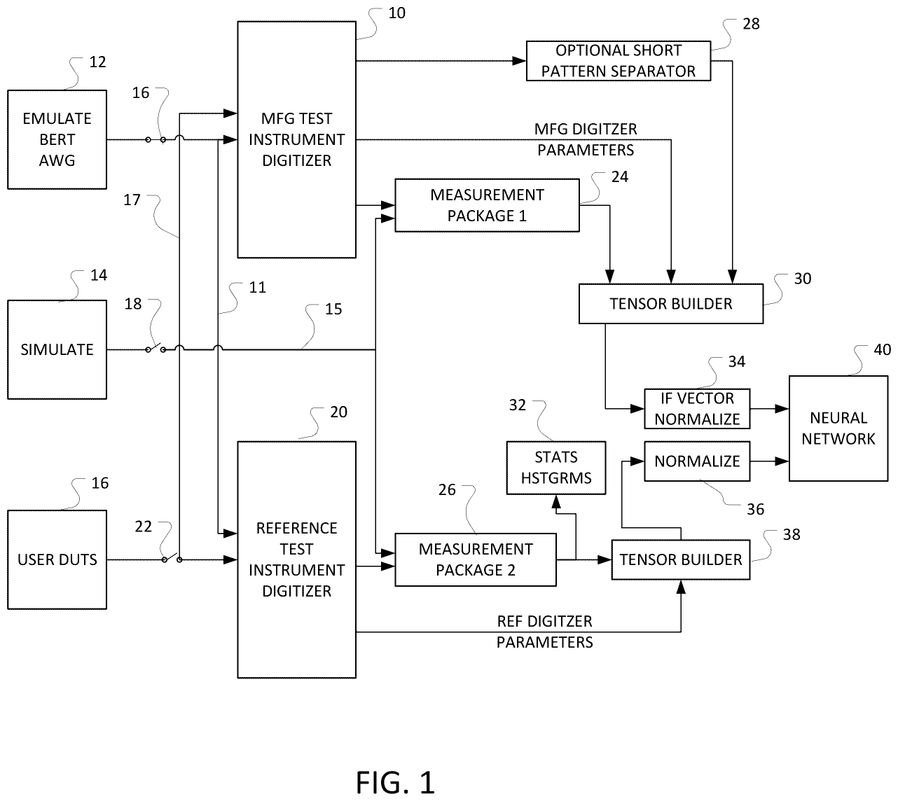

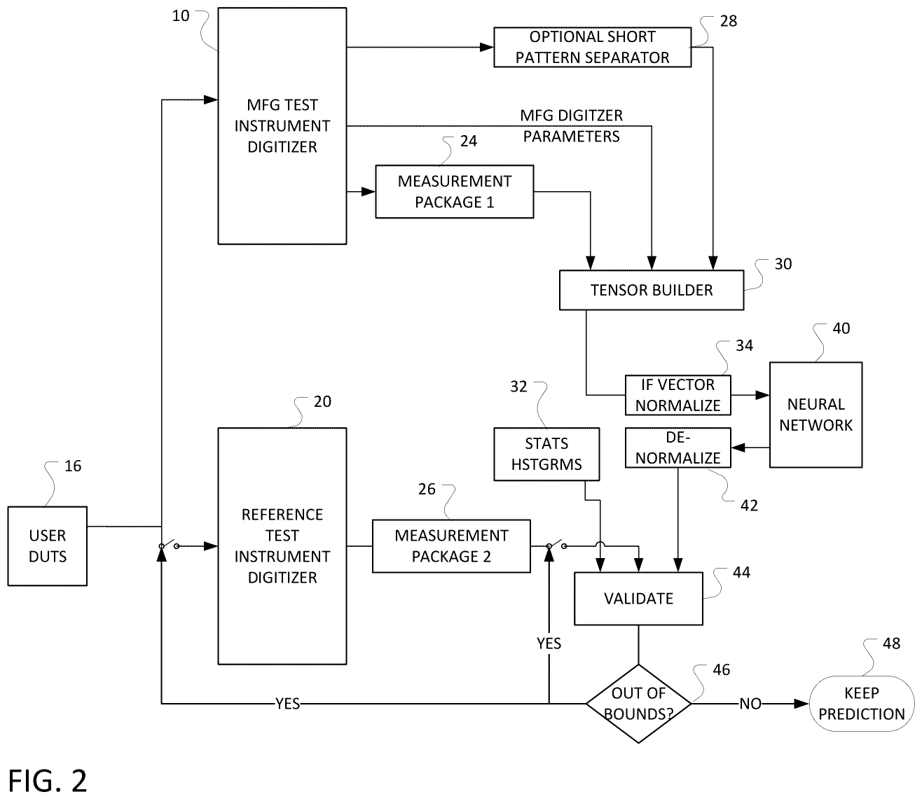

FIGS. 1-2 show an embodiment of a manufacturing system that employs a digitizer in a less expensive manufacturing (MFG) instrument 10 and translates one or more measurements made by the MFG digitizer 10 to the reference digitizer used in reference instrument 20. FIG. 1 shows a configuration in which the neural network 40 undergoes training to associate measurements from the MFG digitizer 10 with the measurements from the reference digitizer 20. Once trained, the neural network 40 may be referred to as trained or pre-trained neural network, which belongs to the user.

FIG. 1 shows three types of waveform input data. There are three types of waveform input data shown in FIG. 1. FIG. 1 shows three types of waveform input data. The Emulate BERT (bit error ratio tester), AWG (arbitrary waveform generator) input 12 represents signal generator hardware that can generate emulations of the desired signals to measure. The resulting waveforms shall be used in the training process of the neural network. The switch 16 shows that the analog waveforms 11 from the BERT are input to both the MFG digitizer 10 and to the reference digitizer 20. It is possible that the neural networks can be fully trained using only the BERT or AWG waveforms and then the trained result can be used to measure DUTs from the user.

Simulate input 14, enabled by switch 18, represents the option that offline simulation software may create waveforms to input into the measurement blocks for training on line 15. The simulation may include models of the oscilloscope and it may include models of user DUTs 16. The switch 18 shows that this is optional input for training the neural network(s).

Actual User DUTs 16 shows where the user's automation test software would control the collection of waveforms from many of the user's DUTs. The resulting waveforms are fed into the MFG digitizer and the reference digitizer and then measured to create the needed training data for the neural networks. Switch 22 shows that these waveforms may be optional for the training process. For example, it is feasible that training using only the BERT input waveforms is all that is necessary for it to then be used to measure DUTs after training is complete.

After measurements package 2 26 takes the measurements of the waveform data, statistics and histogram block 32 calculates statistics of mean, min, max, standard deviation, and histograms from all the training waveforms for all the desired measurements. These shall be used later during runtime to compare neural net output measurements to make a decision for pass or fail of the measured result.

During training, the waveforms made by the MFG digitizer may be converted into a series of short pattern waveforms, as set out in U.S. Patent Publication 20220373598, “SHORT PATTERN WAVEFORM DATABASE MACHINE LEARNING FOR MEASUREMENT,” at short pattern separator 28. The tensor builder 30 takes the waveform, or its short pattern representation, parameters of the MFG digitizer, and the measurements, e.g., from measurement package 1 24, and builds a tensor. The digitizer parameters may include the bandwidth, gain, noise waveforms, effective number of bits, etc. Measurements may include total jitter, duty cycle jitter, data dependent jitter, periodic jitter, non-periodic jitter, random jitter, random noise, periodic noise, data dependent noise, total noise, and non-periodic noise. These are just some examples and are not intended to limit the embodiments to any particular digitizer parameters or measurements. The data may be prepared to fit into a one-dimensional array tensor or vector, or it may be prepared to fit into a 2D, or 3D array such as a monochrome image or an RGB image. Other possibilities exist that may be incorporated. For example, multi branch neural networks may be configured to receive the ID tensor and the 2D or 3D image tensors simultaneously.

The tensor builder 30 may build a tensor vector or an image. If the tensor builder builds a vector, the vector undergoes normalization at 34 and is provided to the neural network in normalized form. To associate the resulting vector with a like vector from the reference instrument 20, the reference digitizer parameters and the measurements are provided to the reference tensor builder 38, which will build a reference tensor vector, which is then normalized at 36. Normalization translates the dynamic range of the input data into a range of −1 to 1 prior to inputting it to the neural network. Denormalization translates the normalized output range back to the expected numerical range of the output measurement data. Normalization may not be included if it already exists internally in the neural network structure. The neural network 40 then associates the measurements represented by the MFG tensor from tensor builder 30 with the tensor with the reference tensor to “teach” the neural network to translate between the different measurements. The user selects the tensor type prior to training and prior to use on the manufacturing line.

FIG. 2 shows a runtime configuration of the trained embodiment from FIG. 1. In the runtime embodiment, the generator data waveform source 12 and the simulated waveform source 14 are not used. The user DUTs 18 generate the waveforms upon which the measurements will be made. Generally, the measurements will be made by the MFG digitizer 10 and the tensor builder 30 will build the MFG tensor. The neural network will now output a result that undergoes denormalization at 42. Reference instrument 10 does not become involved until the validation process at 44. Validation process 44 uses the statistics from 32 and the result from the neural network 40 that is denormalized at 42. The result from the neural network is used to determine if the DUT has passed or failed. This generally involves determining if the value of the measurement lies within the manufacturing tolerances for that measurement at 46. If that measurement lies within the tolerances, the prediction is kept at 48 and the DUT passes. If the measurement lies out of bounds, the reference digitizer 20 then makes the measurement to make a final determination of pass or fail.

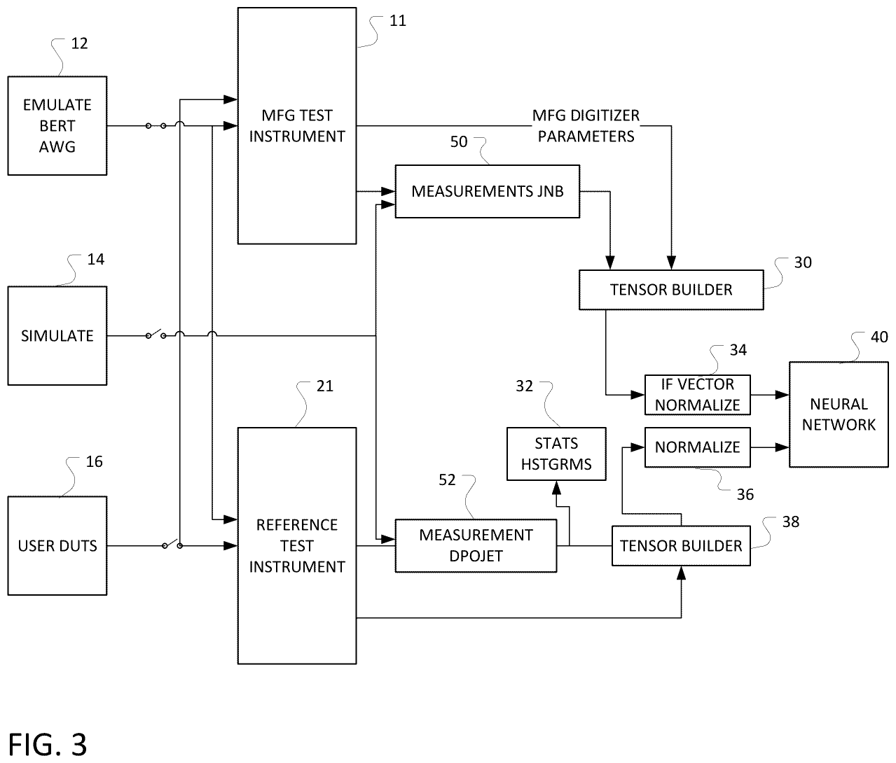

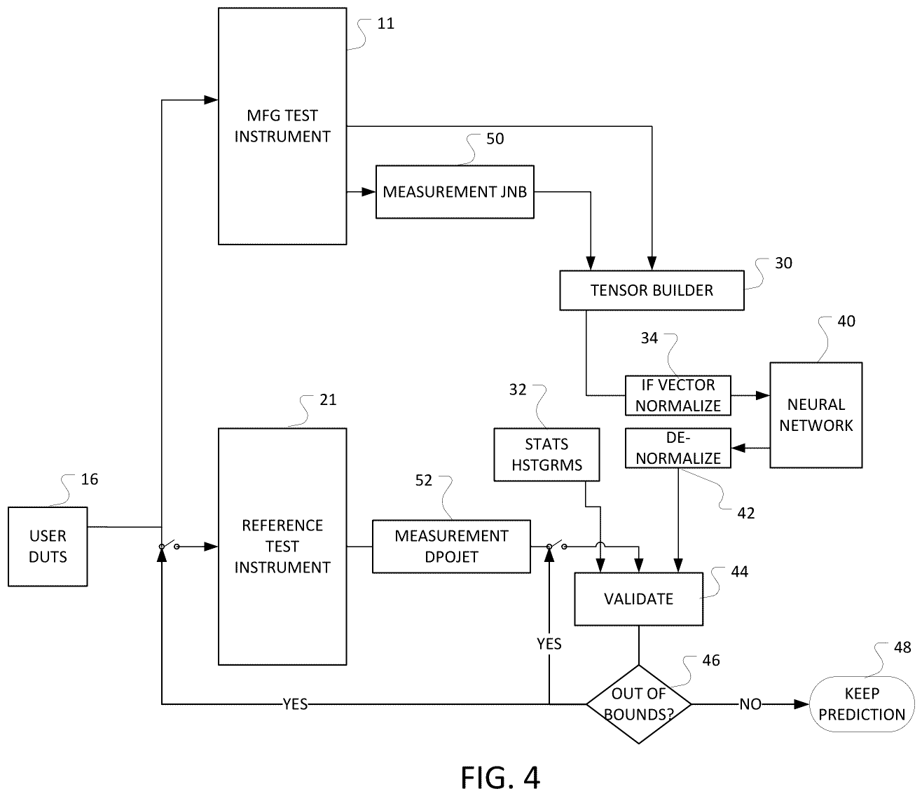

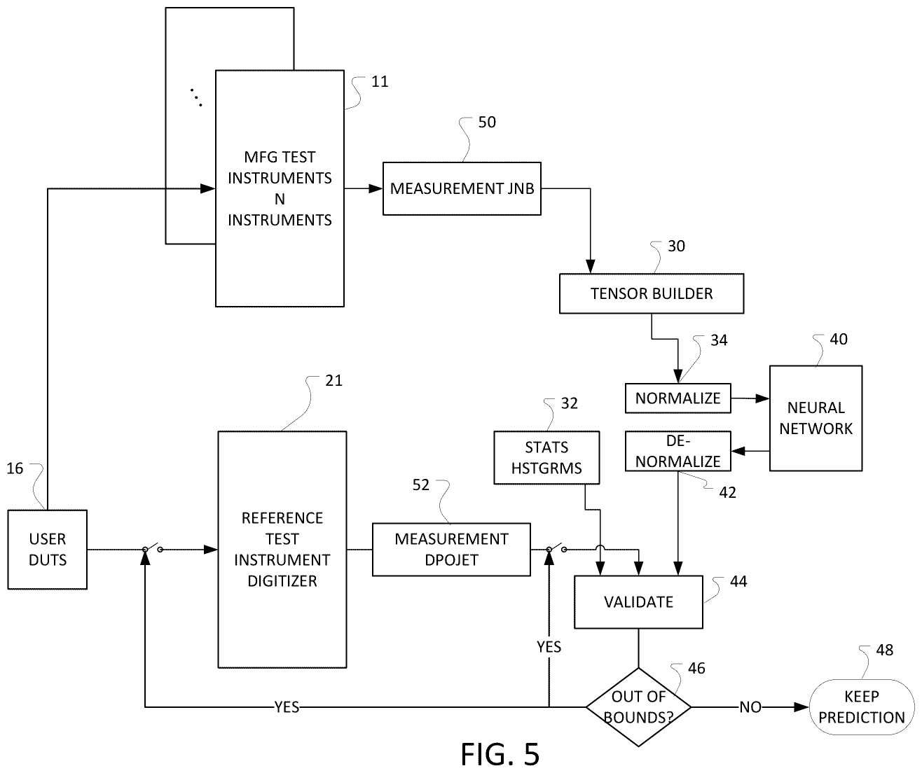

FIGS. 3 and 4 provide a specific example for the more general example of FIGS. 1 and 2. In these processes, the MFG digitizer resides in an MFG test instrument 11, and more specifically within an ET oscilloscope. Similarly, the reference digitizer resides in a reference test instrument 21, in this case an RT scope. The MFG scope will use a JNB measurement package 50, and the reference scope will use Tektronix's DPOJET measurement package 52. FIG. 3 shows the training configuration, similar to FIG. 1 with those changes. FIG. 4 shows the runtime configuration for the configuration of FIG. 3. FIG. 4 may embody a validation process to ensure that the initial testing of the configuration works. In FIG. 5, the runtime configuration has expanded to include multiple instances of the MFG scope 11. Some manufacturing lines may use 100 MFG scopes.

For this example, the customer would have on the order of 100 ET sampling oscilloscopes on their MFG line to take measurements. The customer wishes to use these because they have high bandwidth as needed but cost far less than the RT, real time sampling oscilloscope. The customer in this use case will have one RT scope.

If only one measurement such as non-periodic jitter was input to the neural network for training, the neural network would not have enough information to predict the desired reference value. The mapping could not be made. However, the embodiments rely on the existence of many different measurements. This creates a large multi-dimensional input measurement space which allows for various characteristics of the measured waveform to be seen. The neural network can see this measurement space characterization of the measurement set, and then associate that with the reference measurement space and make a mapping or translation of all of the measurements to what they should be.

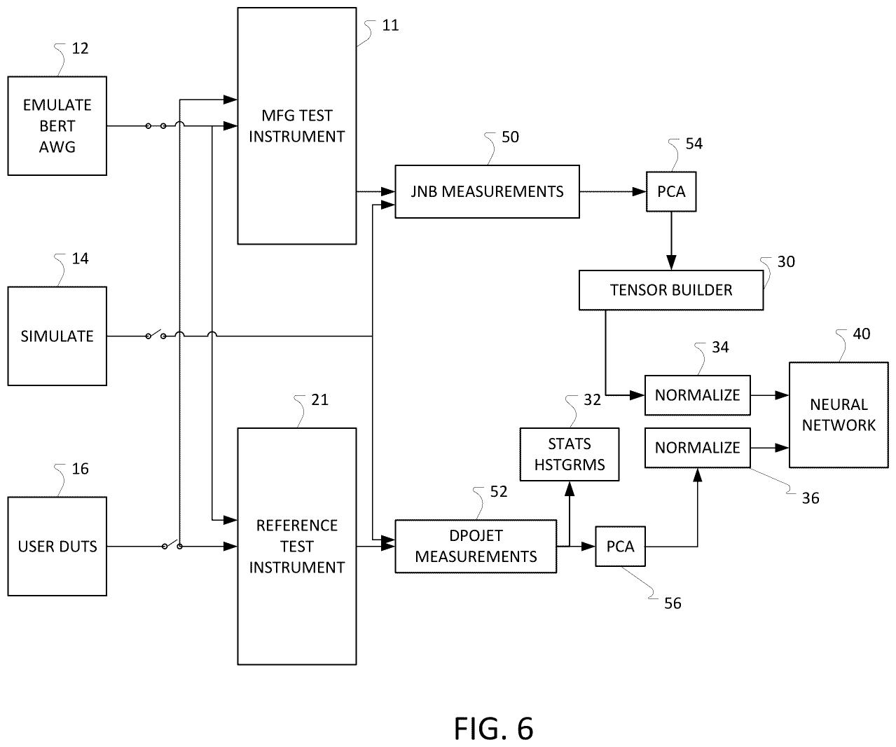

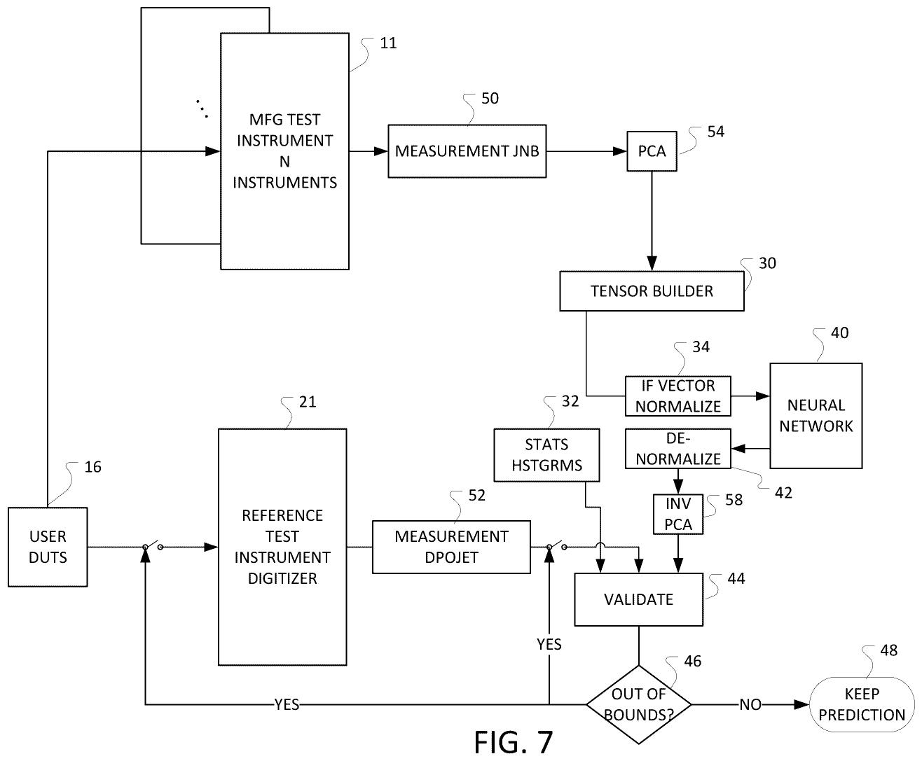

FIGS. 6 and 7 show embodiments of the examples of FIGS. 3 and 4 but with principal component analysis (PCA) added into the system. Adding PCA may provide benefits to train the neural networks. The PCA receives the multiple measurement types and multiple instances of the measurements along the length of the input waveform. The PCA outputs a set of data representing the principal components in those measurements and provides valuable information about how the measurements may be affected by the parameters of the test instrument. Even though the internal neural networks can extract component features of the input data, the PCA may have some additional advantages towards helping to extract out some of the non-linear correlations between all the input measurements. If the neural network outputs a PCA vector, that PCA can be inverse transformed to obtain the desired measurements vectors. PCA is added in the embodiments of the specific JNB/DPOJET example with the understanding that PCA may also be provided in the more general embodiments of FIGS. 1 and 2.

In FIG. 6, the JNB measurement output from 50 undergoes PCA at 54, and that is used to build the MFG tensor at 30. Similarly, the DPOJET measurement output from 52 undergoes PCA at 56 prior to normalization at 36. The neural network then trains on the tensors that include the PCA. FIG. 7 shows the runtime configuration, with the inverse PCA performed at 58 prior to validation at 44.

Returning now to the more general embodiments such as those shown in FIGS. 1 and 2, the embodiments provide the user with the ability to control the digitizers. Specific test instrument parameters may affect the accuracy of the measurements. These parameters may vary as the digitizer settings change, such as vertical gain and offset, or sample rate and bandwidth changes. For example, digitizer noise can change over a wide range with different vertical gain settings.

Inputting these digitizer parameters to the neural network along with the measurements during the training process makes it possible to associate the measurement with different digitizer settings or even different digitizer models if more than one digitizer model type is included in the training process. The metadata would include the array of input measurements and the array of digitizer parameters associated with each measurement set. The label data output from the neural network after training is the desired set of measurements after it has been de-normalized and, if PCA is used, performs inverse PCA.

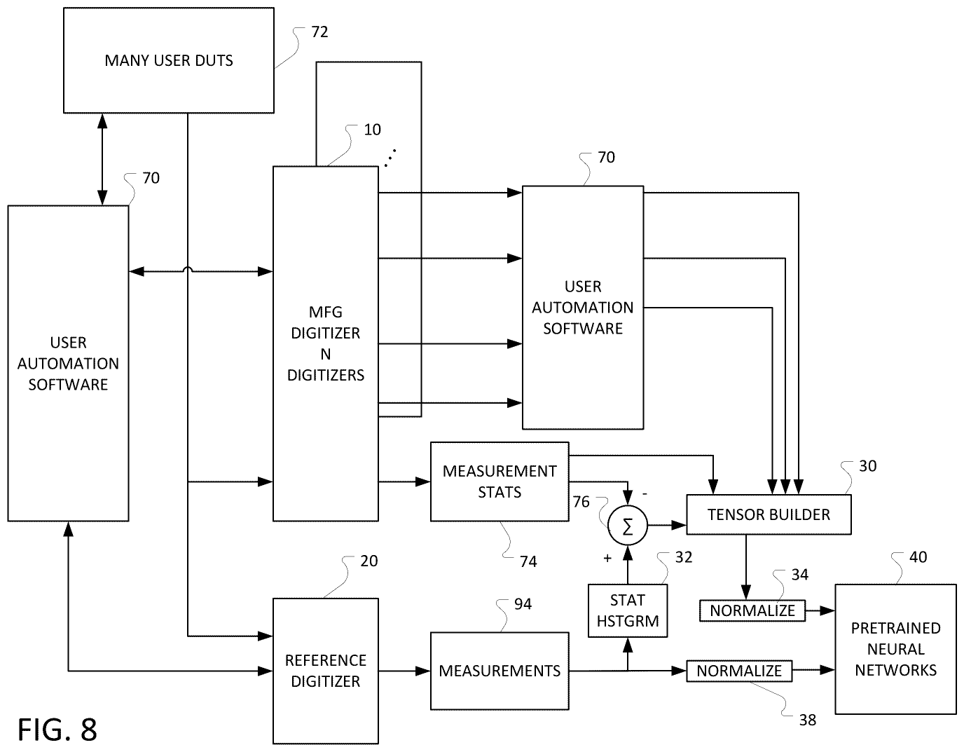

FIG. 8 shows an embodiment of a measurement translator system configuration that includes digitizer parameters for an MFG instrument. The MFG instrument may comprise a scope, a real time spectrum analyzer, or digital multimeter, among many other examples. The user automation software 70 controls the reference digitizer 20 and the array of MFG digitizers such as 10, as they collect and measure waveforms from many user DUTs 72, usually only for training in this instance. Generally, the user automation software controls the DUTs, the test instruments, the measurement requests, etc. The digitizers provide their parameters and settings to the user automation software at 70 and perform measurements and generate the measurement statistics at 74. The measurements 94 from the reference digitizer also undergo statistical and/or histogram analysis at 32, and the results are combined at 76. The combination at 76 improves dynamic range of the measurement result by only inputting the difference between measurements mean and the measured value into the tensor builder block. The tensor builder 30 uses the measurement statistics from 74, the measurement statistics minus the reference statistics, and the digitizer parameters from the user automation software in the form of metadata, normalized at 34 and 38, to build the tensor. The neural network then takes the tensor and the normalized reference measurements as training data. The measurements from the reference digitizer are labeled with the metadata.

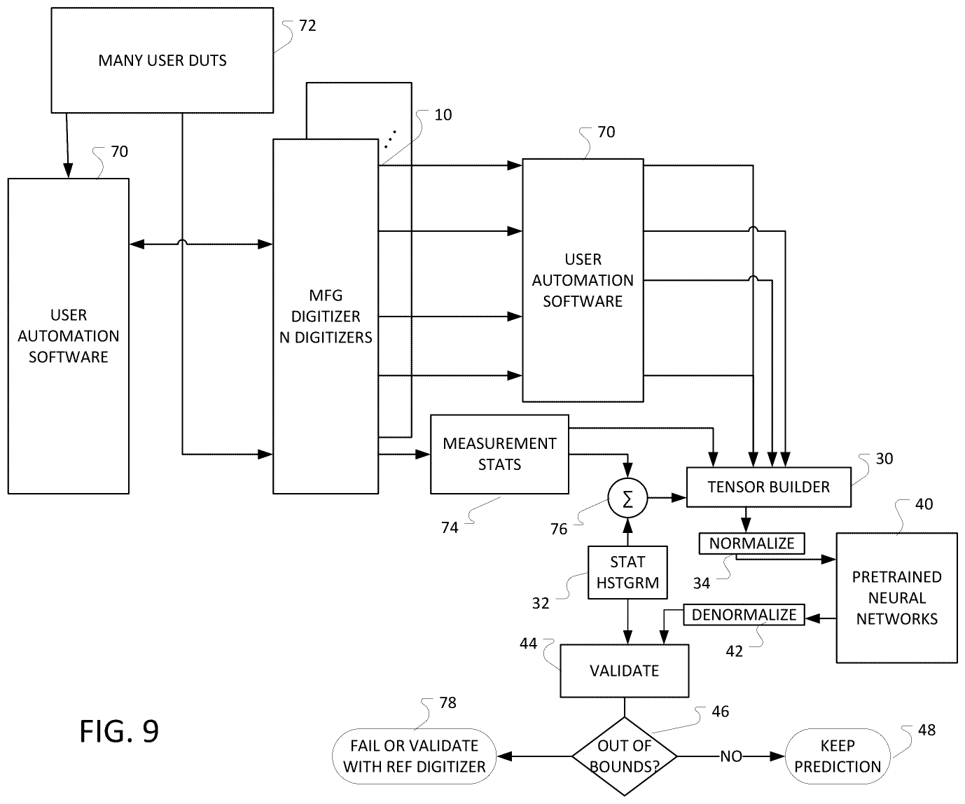

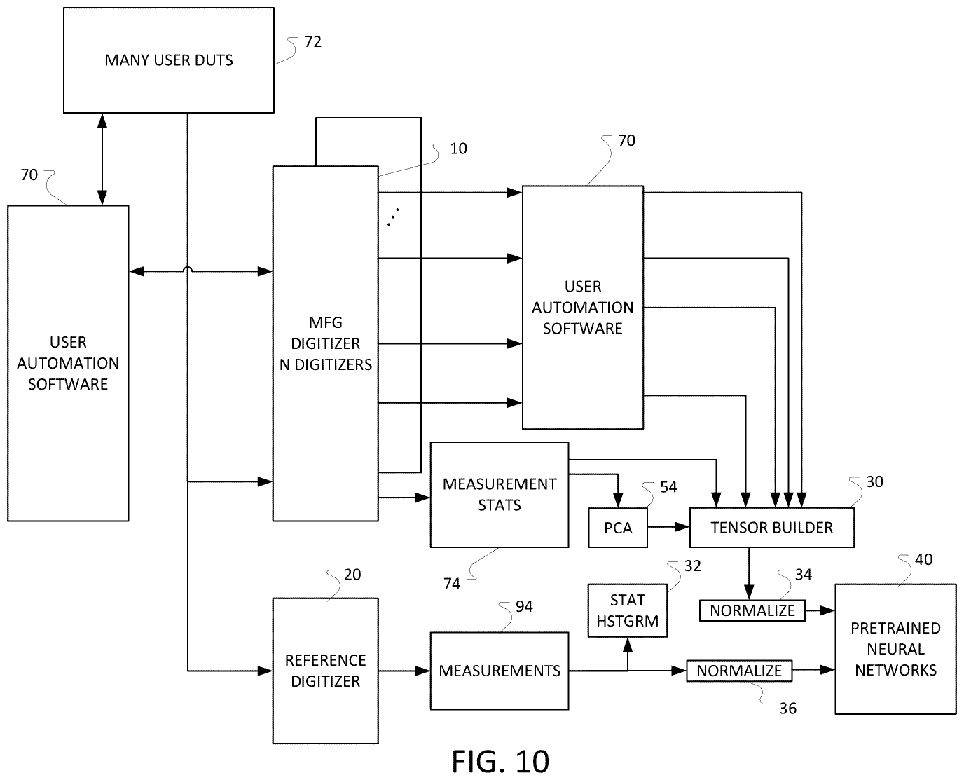

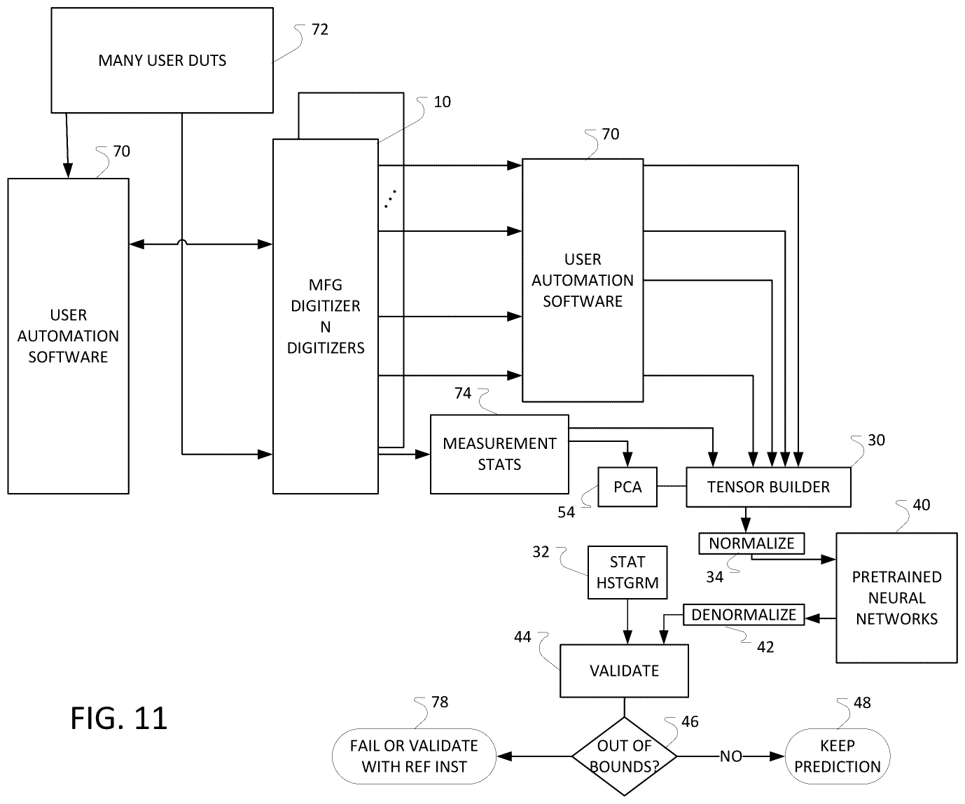

FIG. 9 shows the runtime configuration. FIG. 9 does not show the reference digitizer to simplify the drawings. However, as can be seen at 78, if the validation finds the measurement to be out of bounds, the DUT will either fail, or could undergo re-testing with the reference digitizer. FIG. 10 shows a training configuration that includes PCA 54, with FIG. 11 showing the runtime configuration including PCA.

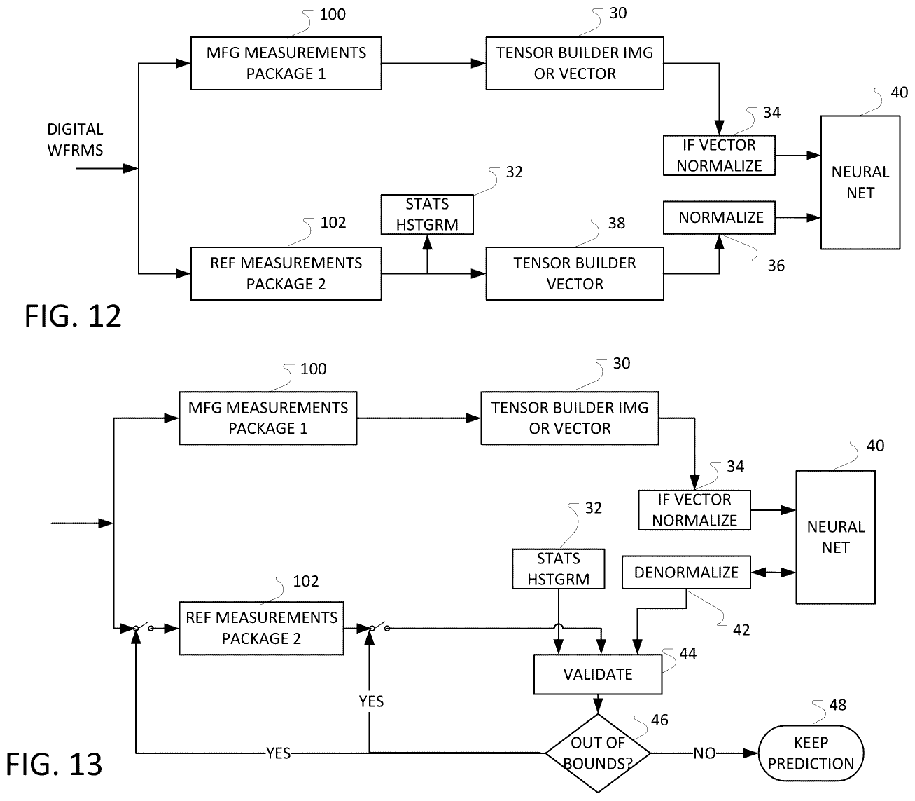

Up to this point, the discussion has focused on MFG digitizers and reference digitizers that are not tied to a particular software measurements package, except for the specific examples relating to JNB and DPOJET. The discussion now turns to embodiments of measurement translation between software packages, shown in FIGS. 12 and 13.

The system consists of a primary block labeled MFG Measurements Package 1, 100, and second block labeled Reference Measurements Package 2, 102. These packages may be the same or different from other measurement packages discussed above. Examples of the translation include, but are not limited to, JNB to DPOJET both owned by Tektronix, EZJIT to DPOJET translator between Keysight and Tektronix, or the reverse, translations between LeCroy or Anritsu and others, etc.

As discussed above, this system uses the large multi-dimensional input measurement space that allows for various characteristics of the measured waveform to be seen. The neural network can see this measurement space characterization of the measurement set, and then associate that with the reference measurement space and make a mapping of all of the measurements to what they should be.

FIG. 12 shows a runtime configuration of a measurement translator between different measurement packages. As discussed above, each measurement package may characterize same or similar measurements differently. The characterizations may vary between the two packages. During training, the MFG package 100 builds a tensor of either an image or a vector, while the reference measurements package 102 does the same. The statistics and histograms are generated at 32 for the reference measurements prior to building the tensor. The neural network then undergoes the training to form the associations between the two. FIG. 13 shows an embodiment of the runtime configuration. Similar to the digitizer examples, the translation measurements undergo validation at 44 and if the DUT fails, the reference instrument using the reference package may take the measurement to confirm pass or fail.

Having discussed the translation between MFG and reference digitizers independent of the measurement packages used, and the translation between measurement packages separate from the digitizers/instruments used, the discussion now turns to embodiments where the test instrument is combined with a particular measurement package. In these embodiments, the neural network translates between the measurements based upon the parameters of the test instruments, and on differences in measurement package/characterizations between the MFG instrument and the reference instrument.

The embodiments in this situation train the neural networks to associate measurements and characteristics parameters of the MFG test instrument with the ideal measurement value from a reference test instrument. The embodiments may be used for many classes of instrumentation. The embodiments use neural networks to take in measurements and statistics from an MFG test instrument. It may also take in the parameters of that instrument which are responsible for the error in the measurements, and then associate that with what the ideal measurement should be. Test instruments may contain digitizers and are generally receiving waveforms as input and then measurement SW produces measurements and statistics on the waveforms. Test instruments may include but are not limited to RT oscilloscopes, ET oscilloscopes, margin testers, BER test systems, real time spectrum analyzers, volt meters, current meters, etc.

Measurement error may be in part due to differences in the test instrument hardware, and also in part due to differences in SW algorithm measurement packages. The embodiments allow for both areas to be considered in the prediction for the translation from a MFG test instrument/measurement set to a reference test instrument/measurement set.

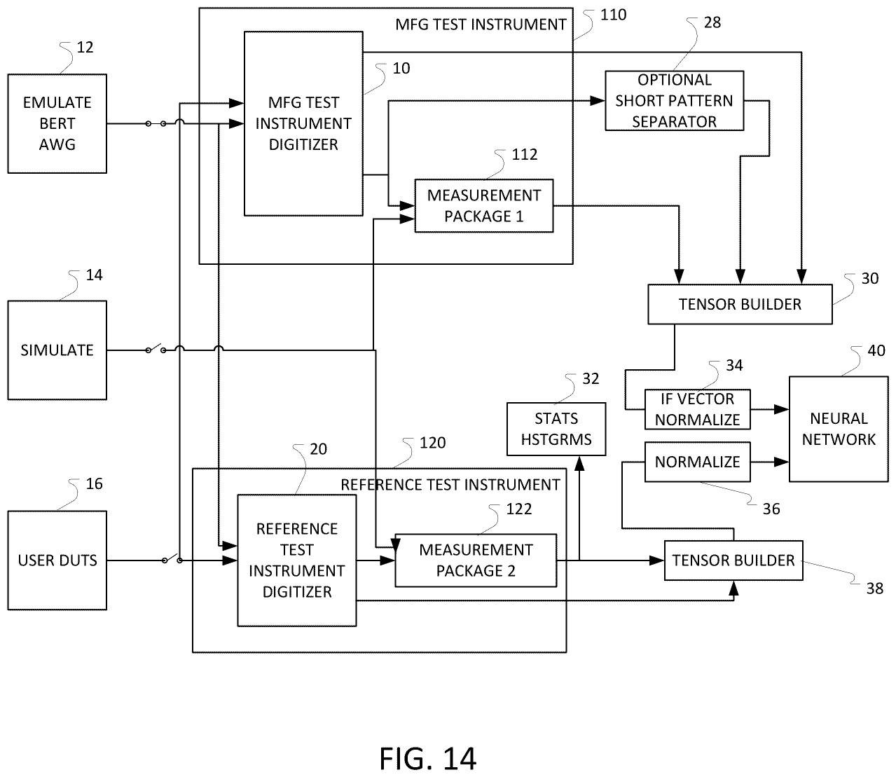

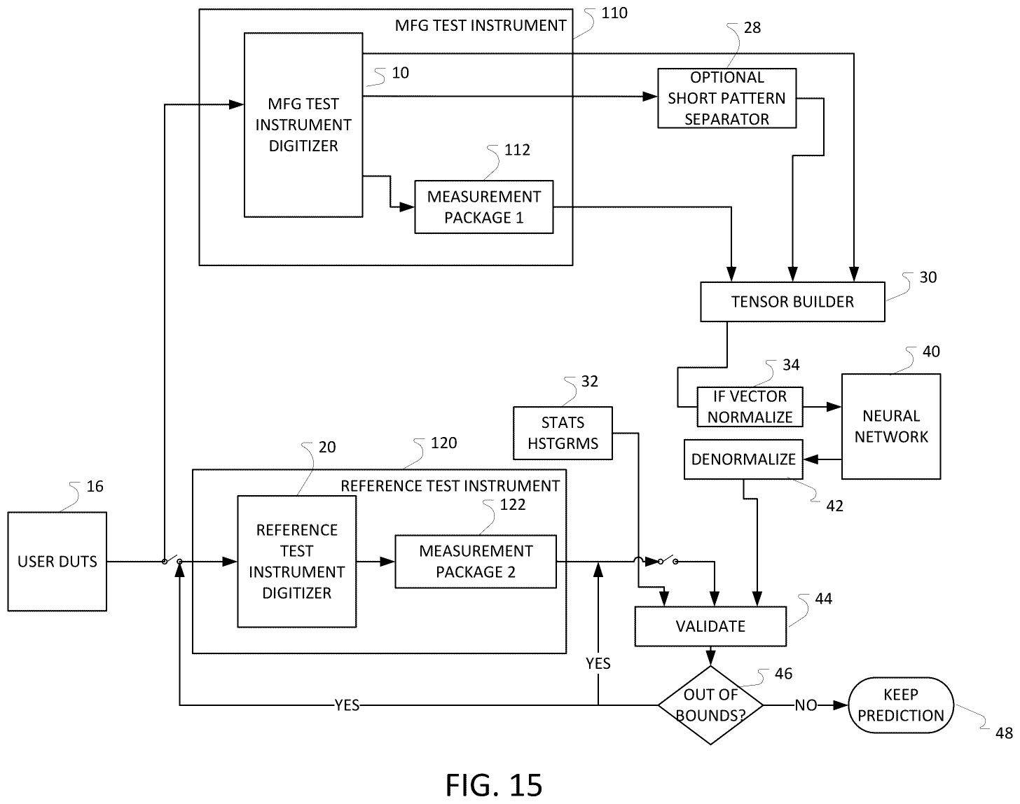

FIGS. 14 and 15 show block diagrams for the combined scope and measurement translation system. This embodiment translates measurements from an MFG test instrument running Measurements Package 1 to match a reference test instrument running Measurements Package 2. The test instrument may be an oscilloscope, spectrum analyzer, voltmeter, current meter, or any other kind of test instrument where a translator might be valuable.

As shown in FIG. 14, the system consists of a primary block labeled MFG TEST INSTRUMENT 110 that contains the digitizer 10, and measurement package 1, 112, and REFERENCE TEST INSTRUMENT 120 that contains the reference digitizer 20 and measurement package 122. Again, this measurement packages 1 and 2 in these embodiments may differ from the ones previously discussed, scope and second block labeled Reference RT scope. The tensor builder 30 will build the tensor using the digitizer and possibly the instrument information with the waveforms, or the short waveforms, and the measurements for the MFG instrument, and the tensor builder 38 will do the same for the reference digitizer, the instrument if used, and the measurements. This trains the system similarly to previous embodiments. FIG. 15 shows the runtime configuration.

These embodiments involve training the neural network 40 so that it can receive a set of jitter and noise values for an input waveform. These measurements are obtained from the MFG instrument 110 and measurements package 1 112 and from the reference instrument 120 and measurement package 2 122. However, in general the instruments may comprise any test instrument having a digitizer. The measurements packages could comprise any software package capable of doing desired measurements on the input digitized data. This data may be waveforms, or it could be voltages from a voltmeter or currents from a current meter and so on. The embodiments transform measurement results from one test instrument and SW to what would be obtained on a different instrument and software. The transformation will take into account any effects that a particular instrument has on the measurements.

The embodiments here provide a novel method of enabling a customer to use a preferred test instrument for MFG test equipment in large quantities and translate the measurements to what they would be on a higher performing reference test instrument. This saves the customer large amounts of money where they may have 100 or more, less expensive MFG test instruments and only one or more expensive reference test instrument. The embodiments provide for translating between MFG and reference test instruments whether they use a measurement package integrated into the instrument, or if the package is separate. The embodiments provide for translating between packages where the instrument and digitizers are not at issue.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the disclosed technologies are provided below. An embodiment of the technologies may include one or more, and any combination of, the examples described below.

Example 1 is a test and measurement system, comprising: a first test and measurement instrument having an input to allow the test and measurement instrument to receive signals from one or more devices under test (DUT) and one or more digitizers to convert the signals from the one or more DUTs to digital waveforms; a machine learning network; and one or more processors configured to execute code that causes the one or more processors to: perform one or more measurements of the digital waveforms; send the one or more measurements of the digital waveforms to the machine learning network as an input; use the machine learning network to translate the one or more measurements to measurements made by a reference instrument to produce one or more translated measurements, the reference instrument being more accurate than the first test and measurement instrument; and determine whether the DUT meets a performance requirement based upon the one or more translated measurements.

Example 2 is the test and measurement system of Example 1, wherein the code that causes the one or more processors to send the one or more measurements to the machine learning system comprises code that causes the one or more processors to send one or more digitizer parameters with the one or more measurements to a tensor builder prior to the machine learning network.

Example 3 is the test and measurement system of either of Examples 1 or 2, wherein the code that causes the one or more processors to send the one or more measurements to the machine learning system comprises code that causes the one or more processors to send one or more measurement statistics with the one or more measurements to a tensor builder prior to the machine learning network.

Example 4 is the test and measurement system of Any of Examples 1 through 3, wherein the code that causes the one or more processors to send the one or more measurement statistics comprises code to send a set of principal components with the one or more measurements to a tensor builder prior to the machine learning network.

Example 5 is the test and measurement system of Example 2, wherein the one or more processors are further configured to execute code to build a tensor from the one or more digitizer parameters and the one or more measurements to send to the machine learning network.

Example 6 is the test and measurement system of Any of Examples 1 through 5, wherein the code that causes the one or more processors to send the one or more measurements to the machine learning system comprises code that causes the one or more processors to separate the digital waveforms into one or more short pattern waveforms and to send the short pattern waveforms to a tensor builder prior to the machine learning network.

Example 7 is the test and measurement system of Any of Examples 1 through 6, wherein the code that causes the one or more processors to determine whether the DUT meets the performance requirement based on the one or more translated measurements comprises code that causes the one or more processors to determine that the DUT does not meet the performance requirement, and the one or more processors are further configured to execute code that causes the one or more processors to: direct the reference instrument to digitize signals from the DUT and perform a same one or more measurements on digital waveforms; and determine whether the DUT meets the performance requirement based upon the one or more measurements from the reference instrument.

Example 8 is the test and measurement system of Any of Examples 1 through 7, wherein the code that causes the one or more processors to determine whether the DUT meets the performance requirement based on the one or more translated measurements from the machine learning network, comprises code to cause the one or more processors to determining that the DUT does not meet the performance requirement, and the one or more processors are further configured to execute code that causes the one or more processors to report the DUT as failed.

Example 9 is the test and measurement system of Any of Examples 1 through 8, wherein the one or more processors are further configured to execute code that causes the one or more processors to train the machine learning network.

Example 10 is the test and measurement system of Any of Examples 1 through 9, wherein the one or more processors are further configured to execute code that causes the one or more processors to train the machine learning network and the code that causes the one or more processors to train the machine learning network comprises code that causes the one or more processors to: receive one or more measurements on digital waveforms from the first test and measurement instrument; receive one or more measurements on the digital waveforms from the reference instrument; and associate the one or more measurements from the first test and measurement instrument to corresponding ones of the one or more measurements from the reference instrument.

Example 11 is the test and measurement system of Any of Examples 1 through 10, wherein the one or more processors are further configured to execute code that causes the one or more processors to perform at least one of calculate statistics of the measurements and perform principal component analysis of the measurements to associate at least one of the statistics and the principal components with the measurements.

Example 12 is the test and measurement instrument of Any of Examples 1 through 11, wherein: the code that causes the one or more processors to perform the one or more measurements of the digital waveforms comprises code that causes the one or more processors to perform the one or more measurements using a first characterization of the one or more measurements; the code that causes the one or more processors to send the one or more measurements of the digital waveforms to the machine learning network as an input comprises code that causes the one or more processors to send the one or more measurements of the digital waveforms and the first characterization to the machine learning network as an input; and the code that causes the one or more processors to use the machine learning network to translate the one or more measurements to measurements made by the reference instrument causes the one or more processors to map the one or more measurements made using the first characterization to one or more measurements to measurements made by a reference instrument using a second characterization.

Example 13 is a test and measurement system, comprising: a first test and measurement instrument having an input to allow the test and measurement instrument to receive signals from one or more devices under test (DUT) and one or more digitizers to convert the signals from the DUT to digital waveforms; a machine learning network; one or more processors configured to execute code that causes the one or more processors to: perform one or more measurements of the digital waveforms using the first test and measurement instrument, the first test and measurement instrument using a first characterization of the one or more measurements; send the one or more measurements of the digital waveforms and the first characterization to the machine learning network as an input; use the machine learning network to translate the one or more measurements to measurements made by a reference instrument to produce one or more translated measurements, the reference instrument being more accurate than the first test and measurement instrument and using a second characterization of the one or more measurements; and determine, using the one or more translated measurements from the machine learning network, whether the DUT meets performance requirements.

Example 14 is the test and measurement system of Example 13, wherein the code that causes the one or more processors to send the one or more measurements to the machine learning system comprises code that causes the one or more processors to send one or more digitizer parameters with the one or more measurements to a tensor builder prior to the machine learning network.

Example 15 is the test and measurement system of either of Examples 13 and 14, wherein the code that causes the one or more processors to send the one or more measurements and the first characterization to the machine learning system comprises code that causes the one or more processors to send one or more measurement statistics with the one or more measurements and the first characterization to a tensor builder prior to the machine learning network.

Example 16 is the test and measurement system of Example 15, wherein the code that causes the one or more processors to send one or more measurement statistics with the one or more measurements to a tensor builder prior to the machine learning network comprises code to send a set of principal components with the one or more measurements to a tensor builder prior to the machine learning network.

Example 17 is the test and measurement system of any of Examples 13 through 16, wherein the one or more processors are further configured to execute code to build a tensor from the one or more digitizer parameters and the one or more measurements to send to the machine learning network.

Example 18 is the test and measurement system of any of Examples 13 through 17, wherein the code that causes the one or more processors to send the one or more measurements to the machine learning system comprises code that causes the one or more processors to separate the digital waveforms into one or more short pattern waveforms and to send the short pattern waveforms to a tensor builder prior to the machine learning network.

Example 19 is the test and measurement system of any of Examples 13 through 18, wherein the code that causes the one or more processors to determine, using one or more translated measurements from the machine learning network, comprises code that causes the one or more processors to determine, using one or more of the translated measurements, that the DUT does not meet the performance requirement, and the one or more processors are further configured to execute code that causes the one or more processors to: direct the reference instrument to digitize signals from the DUT and perform a same one or more measurements on digital waveforms; and determine whether the DUT meets the performance requirement based upon the one or more measurements from the reference instrument.

Example 20 is the test and measurement system of any of Examples 13 through 19, wherein the one or more processors are further configured to execute code that causes the one or more processors to train the machine learning network and the code that causes the one or more processor to train the machine learning network causes the one or more processors to: receive one or more measurements on digital waveforms from the first test and measurement instrument using the first characterization; receive one or more measurements on digital waveforms from the reference test and measurement instrument using the second characterization; and associate the one or more measurements and the first characterization of the one or more measurements from the first test and measurement instrument to corresponding ones of the one or more measurements and the second characterization of the one or more measurements from the reference test and measurement instrument.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Although specific examples of the invention have been illustrated and described for purposes of illustration, it will be understood that various modifications may be made without departing from the spirit and scope of the invention. Accordingly, the invention should not be limited except as by the appended claims.

1. A test and measurement system, comprising:
a first test and measurement instrument having an input to allow the test and measurement instrument to receive signals from one or more devices under test (DUT) and one or more digitizers to convert the signals from the one or more DUTs to digital waveforms;
a machine learning network; and
one or more processors configured to execute code that causes the one or more processors to:
perform one or more measurements of the digital waveforms;
send the one or more measurements of the digital waveforms to the machine learning network as an input;
use the machine learning network to translate the one or more measurements to measurements made by a reference instrument to produce one or more translated measurements, the reference instrument being more accurate than the first test and measurement instrument; and
determine whether the DUT meets a performance requirement based upon the one or more translated measurements.

2. The test and measurement system as claimed in claim 1, wherein the code that causes the one or more processors to send the one or more measurements to the machine learning system comprises code that causes the one or more processors to send one or more digitizer parameters with the one or more measurements to a tensor builder prior to the machine learning network.

3. The test and measurement system as claimed in claim 1, wherein the code that causes the one or more processors to send the one or more measurements to the machine learning system comprises code that causes the one or more processors to send one or more measurement statistics with the one or more measurements to a tensor builder prior to the machine learning network.

4. The test and measurement system as claimed in claim 1, wherein the code that causes the one or more processors to send the one or more measurement statistics comprises code to send a set of principal components with the one or more measurements to a tensor builder prior to the machine learning network.

5. The test and measurement system as claimed in claim 2, wherein the one or more processors are further configured to execute code to build a tensor from the one or more digitizer parameters and the one or more measurements to send to the machine learning network.

6. The test and measurement system as claimed in claim 1, wherein the code that causes the one or more processors to send the one or more measurements to the machine learning system comprises code that causes the one or more processors to separate the digital waveforms into one or more short pattern waveforms and to send the short pattern waveforms to a tensor builder prior to the machine learning network.

7. The test and measurement system as claimed in claim 1, wherein the code that causes the one or more processors to determine whether the DUT meets the performance requirement based on the one or more translated measurements comprises code that causes the one or more processors to determine that the DUT does not meet the performance requirement, and the one or more processors are further configured to execute code that causes the one or more processors to:
direct the reference instrument to digitize signals from the DUT and perform a same one or more measurements on digital waveforms; and
determine whether the DUT meets the performance requirement based upon the one or more measurements from the reference instrument.

8. The test and measurement system as claimed in claim 1, wherein the code that causes the one or more processors to determine whether the DUT meets the performance requirement based on the one or more translated measurements from the machine learning network, comprises code to cause the one or more processors to determining that the DUT does not meet the performance requirement, and the one or more processors are further configured to execute code that causes the one or more processors to report the DUT as failed.

9. The test and measurement system as claimed in claim 1, wherein the one or more processors are further configured to execute code that causes the one or more processors to train the machine learning network.

10. The test and measurement system as claimed in claim 1, wherein the one or more processors are further configured to execute code that causes the one or more processors to train the machine learning network and the code that causes the one or more processors to train the machine learning network comprises code that causes the one or more processors to:
receive one or more measurements on digital waveforms from the first test and measurement instrument;
receive one or more measurements on the digital waveforms from the reference instrument; and
associate the one or more measurements from the first test and measurement instrument to corresponding ones of the one or more measurements from the reference instrument.

11. The test and measurement system as claimed in claim 10, wherein the one or more processors are further configured to execute code that causes the one or more processors to perform at least one of calculate statistics of the measurements and perform principal component analysis of the measurements to associate at least one of the statistics and the principal components with the measurements.

12. The test and measurement instrument as claimed in claim 1, wherein:
the code that causes the one or more processors to perform the one or more measurements of the digital waveforms comprises code that causes the one or more processors to perform the one or more measurements using a first characterization of the one or more measurements;
the code that causes the one or more processors to send the one or more measurements of the digital waveforms to the machine learning network as an input comprises code that causes the one or more processors to send the one or more measurements of the digital waveforms and the first characterization to the machine learning network as an input; and
the code that causes the one or more processors to use the machine learning network to translate the one or more measurements to measurements made by the reference instrument causes the one or more processors to map the one or more measurements made using the first characterization to one or more measurements to measurements made by a reference instrument using a second characterization.

13. A test and measurement system, comprising:
a first test and measurement instrument having an input to allow the test and measurement instrument to receive signals from one or more devices under test (DUT) and one or more digitizers to convert the signals from the DUT to digital waveforms;
a machine learning network;
one or more processors configured to execute code that causes the one or more processors to:
perform one or more measurements of the digital waveforms using the first test and measurement instrument, the first test and measurement instrument using a first characterization of the one or more measurements;
send the one or more measurements of the digital waveforms and the first characterization to the machine learning network as an input;
use the machine learning network to translate the one or more measurements to measurements made by a reference instrument to produce one or more translated measurements, the reference instrument being more accurate than the first test and measurement instrument and using a second characterization of the one or more measurements; and
determine, using the one or more translated measurements from the machine learning network, whether the DUT meets performance requirements.

14. The test and measurement system as claimed in claim 13, wherein the code that causes the one or more processors to send the one or more measurements to the machine learning system comprises code that causes the one or more processors to send one or more digitizer parameters with the one or more measurements to a tensor builder prior to the machine learning network.

15. The test and measurement system as claimed in claim 13, wherein the code that causes the one or more processors to send the one or more measurements and the first characterization to the machine learning system comprises code that causes the one or more processors to send one or more measurement statistics with the one or more measurements and the first characterization to a tensor builder prior to the machine learning network.

16. The test and measurement system as claimed in claim 15, wherein the code that causes the one or more processors to send one or more measurement statistics with the one or more measurements to a tensor builder prior to the machine learning network comprises code to send a set of principal components with the one or more measurements to a tensor builder prior to the machine learning network.

17. The test and measurement system as claimed in claim 13, wherein the one or more processors are further configured to execute code to build a tensor from the one or more digitizer parameters and the one or more measurements to send to the machine learning network.

18. The test and measurement system as claimed in claim 13, wherein the code that causes the one or more processors to send the one or more measurements to the machine learning system comprises code that causes the one or more processors to separate the digital waveforms into one or more short pattern waveforms and to send the short pattern waveforms to a tensor builder prior to the machine learning network.

19. The test and measurement system as claimed in claim 13, wherein the code that causes the one or more processors to determine, using one or more translated measurements from the machine learning network, comprises code that causes the one or more processors to determine, using one or more of the translated measurements, that the DUT does not meet the performance requirement, and the one or more processors are further configured to execute code that causes the one or more processors to:
direct the reference instrument to digitize signals from the DUT and perform a same one or more measurements on digital waveforms; and
determine whether the DUT meets the performance requirement based upon the one or more measurements from the reference instrument.

20. The test and measurement system as claimed in claim 13, wherein the one or more processors are further configured to execute code that causes the one or more processors to train the machine learning network and the code that causes the one or more processor to train the machine learning network causes the one or more processors to:
receive one or more measurements on digital waveforms from the first test and measurement instrument using the first characterization;
receive one or more measurements on digital waveforms from the reference test and measurement instrument using the second characterization; and
associate the one or more measurements and the first characterization of the one or more measurements from the first test and measurement instrument to corresponding ones of the one or more measurements and the second characterization of the one or more measurements from the reference test and measurement instrument.
